(19) United States
(12) Patent Application Publication
(10) Pub. No.: US 2010/0022094 A1
(43) Pub. Date: Jan. 28, 2010

(54) ELEVATOR AND APPARATUS AND METHOD FOR PROCESSING SUBSTRATE USING THE SAME

(75) Inventors: Geun-Ho Kim, Gyeonggi-do (KR); Seung-Il Park, Gyeonggi-do (KR)

Correspondence Address: DALY, CROWLEY, MOFFORD & DURKEE, LLP, SUITE 301A, 354A TURNPIKE STREET, CANTON, MA, 02021-2714, US

(73) Assignee: SOSUL CO., LTD., Yongin-si, Gyeonggi-do (KR)

(21) Appl. No.: 12/527,062

(22) PCT Filed: Mar. 7, 2008
(86) PCT No.: PCT/KR2008/001327

§ 371 Date: Aug. 13, 2009

(30) Foreign Application Priority Data
Mar. 8, 2007 (KR) 10-2007-0022905
Mar. 8, 2007 (KR) 10-2007-0022909

(51) Int. Cl. H01L 21/465; H01L 21/67

(52) U.S. Cl. 438/716; 414/222.01; 414/222.13; 257/E21.485

(57) ABSTRACT

In an apparatus and a method for processing a substrate, a plurality of chucks are disposed parallel with each other in a process chamber. The chucks fully support back surfaces of substrates and have a plurality of through-holes. Supports are disposed through the through-holes and movable in a vertical direction. The substrates are loaded on the chucks or unloaded from the chucks by relative movement between the chucks and the supports. Thus, an unwanted layer may be prevented from being formed on the back surfaces of the substrates while processing the substrates.

### TECHNICAL FIELD

The present invention relates to an apparatus and a method for processing a substrate using an elevator. More particularly, the present invention relates to an apparatus and a method for processing a plurality of substrates using an elevator which loads the substrates into one chamber and unloads the substrates from the chamber.

### BACKGROUND ART

An apparatus for processing a semiconductor substrate may generally be classified as a batch-type apparatus which simultaneously processes a plurality of substrates using one process chamber or a single-type apparatus which individually processes substrates one by one in one chamber. Particularly, in a case of a high-temperature process, which processes a substrate at a high-temperature, a long time is required to adjust a temperature in a chamber. Thus, a batch-type apparatus is generally employed in a high-temperature process.

However, when using a batch-type apparatus, an unwanted layer including impurities may be formed on back surfaces of semiconductor substrates. The unwanted layer may function as a contamination source while performing a subsequent process, such as an etching process, a cleaning process, an etch-back process, and the like.

Further, when using a batch-type apparatus, semiconductor substrates may be arranged parallel with one another in a boat. In this case, it is difficult to uniformly supply a plasma, which is generated to process the semiconductor substrates in a chamber, onto the semiconductor substrates. Moreover, a long time is required to adjust a pressure in the chamber or in a transfer chamber and to move the boat.

### DISCLOSURE OF THE INVENTION

### Technical Problem

One object of the present invention is to provide an elevator for moving a plurality of substrates in a vertical direction.

Another object of the present invention is to provide an apparatus for processing a substrate capable of simultaneously processing a plurality of substrates using the elevator as described above and preventing an unwanted layer from being formed on back surfaces of the substrates.

Still another object of the present invention is to provide a method of processing a substrate capable of simultaneously processing a plurality of substrates using the substrate processing apparatus as described above and preventing an unwanted layer from being formed on back surfaces of the substrates.

### Technical Solution

An elevator, according to one aspect of the present invention, may include first plates disposed in a horizontal direction with each other; a first support unit supporting the first plates; a second plate disposed parallel to the first plates between the first plates; a second support unit supporting the second plate; a first driving shaft connected with the first support unit, the first driving shaft having a hollow therein and extending in a vertical direction; a second driving shaft connected with the second support unit, the second driving shaft extending through the hollow of the first driving shaft; and a driving unit mechanically connected with the first and second driving shafts to move the first and second driving shafts in the vertical direction.

According to some example embodiments of the present invention, the driving unit may include a first flange connected with an end of the first driving shaft, a second flange disposed parallel to the first flange under the first flange and connected with an end of the second driving shaft, a driving section moving the second flange in the vertical direction, and a distance-adjusting member connecting the first and second flanges with each other and adjusting a distance between the first and second flanges.

According to some example embodiments of the present invention, the distance-adjusting member may include a hydraulic or pneumatic cylinder.

According to some example embodiments of the present invention, the driving unit may further include a bellows surrounding the second driving shaft between the first and second flanges.

An apparatus for processing a substrate, according to another aspect of the present invention, may include a process chamber; a plurality of chucks disposed parallel with each other in the process chamber, the chucks supporting a plurality of substrates to make contact with back surfaces of the substrates and each having a plurality of through-holes; and a plurality of supports disposed through the through-holes, the supports loading the substrates on the chucks and unloading the substrates from the chucks.

According to some example embodiments of the present invention, each of the chucks may be in full contact with each of the back surfaces of the substrates.

According to some example embodiments of the present invention, the chucks may be vertically movable to support the substrates and to unload the supported substrates.

According to some example embodiments of the present invention, the substrate processing apparatus may further include heaters disposed within the chucks to adjust the temperature of the substrates.

According to some example embodiments of the present invention, the substrate processing apparatus may further include a driving unit to simultaneously move the chucks in a vertical direction.

According to some example embodiments of the present invention, the substrate processing apparatus may further include a support unit supporting the chucks and extending in the vertical direction and a driving shaft connecting the support unit with the driving unit.

According to some example embodiments of the present invention, the substrate processing apparatus may further include a plurality of plates disposed parallel to the chucks under the chucks and dividing a space in the process chamber so that the substrates are processed in individual spaces.

According to some example embodiments of the present invention, the plates may support ends of the supports and may be vertically movable.

According to some example embodiments of the present invention, the plates may include a conductive material.

According to some example embodiments of the present invention, the plates may have a diameter greater than those of the chucks.

According to some example embodiments of the present invention, the substrate processing apparatus may further include a driving unit moving the plates in a vertical direction.

According to some example embodiments of the present invention, the substrate processing apparatus may further include a support unit supporting the plates and extending in the vertical direction and a driving shaft connecting the support unit with the driving unit.

According to some example embodiments of the present invention, each of the plates may have a plurality of second through-holes to pass a gas for processing the substrates therethrough.

According to some example embodiments of the present invention, the second through-holes may have a diameter of about 0.05 to about 5 mm.

According to some example embodiments of the present invention, the plates may include aluminum, tantalum, titanium, silver or an alloy thereof.

According to some example embodiments of the present invention, the plates may have a multilayer structure.

According to some example embodiments of the present invention, each of the plates may include a conductive layer and an insulating layer on the conductive layer.

According to some example embodiments of the present invention, each of the plates may include a conductive layer, an insulating layer on the conductive layer and an adiabatic layer on the insulating layer.

According to some example embodiments of the present invention, each of the plates may have a cooling line configured to circulate a cooling agent.

According to some example embodiments of the present invention, the chucks may include a conductive material.

According to some example embodiments of the present invention, the substrate processing apparatus may further include a heater adjusting a temperature in the process chamber.

An apparatus for processing a substrate, according to still another aspect of the present invention, may include a process chamber; a plurality of chucks disposed parallel with each other in the process chamber, the chucks each supporting a plurality of substrates to each make contact with back surfaces of the substrates and having a plurality of through-holes; a plurality of supports disposed through the through-holes and movable in a vertical direction; a first support unit supporting the chucks and extending in the vertical direction; plates disposed parallel to the chucks under the chucks to support lower ends of the supports; a second support unit supporting the plates and extending in the vertical direction; a first driving shaft connected with the first support unit, the first driving shaft having a hollow therein and extending in the vertical direction; a second driving shaft connected with the second support unit, the second driving shaft extending through the hollow of the first driving shaft; and a driving unit mechanically connected with the first and second driving shafts to move the first and second driving shafts in the vertical direction.

A method of processing a substrate, according to still another aspect of the present invention, may include loading a plurality of substrates on a plurality of chucks, respectively, the chucks being disposed parallel with each other in a process chamber and having a plurality of through-holes; processing the substrates using a process gas; unloading the substrates from the chucks by allowing supports to support the substrates, the supports being disposed through the through-holes and movable in a vertical direction; and carrying the substrates spaced apart from the chucks out from the process chamber.

According to some example embodiments of the present invention, the substrates may be supported by the supports by moving the chucks downward.

According to some example embodiments of the present invention, the substrates may be supported by the supports by moving the supports upward.

### ADVANTAGEOUS EFFECTS

According to the example embodiments of the present invention, a plurality of substrates may be processed in one chamber using a plasma. Particularly, chucks may be disposed in the chamber to fully support back surfaces of the substrates. Thus, an unwanted layer may be prevented from being formed on the back surfaces of the substrates.

### BRIEF DESCRIPTION OF THE DRAWINGS

The above and other advantages of the present invention will become more apparent by describing example embodiments thereof in detail with reference to the accompanying drawings, in which:

FIG. 1 is a cross-sectional view illustrating an elevator according to an example embodiment of the present invention;

FIG. 2 is a perspective view illustrating first and second driving shafts shown in FIG. 1;

FIG. 3 is a cross-sectional view illustrating an apparatus for processing a substrate according to another example embodiment of the present invention;

FIG. 4 is a plan view illustrating a state in which the substrate is supported in the substrate processing apparatus shown in FIG. 3;

FIG. 5 is a cross-sectional view illustrating the substrate supported by first and second support units shown in FIG. 3;

FIG. 6 is a cross-sectional view illustrating the substrate spaced apart from a chuck by the first support unit shown in FIG. 3;

FIG. 7 is a cross-sectional view illustrating the substrate spaced apart from the chuck by the second support unit shown in FIG. 3;

FIG. 8 is a plan view illustrating an example of the plate shown in FIG. 3;

FIG. 9 is a cross-sectional view illustrating another example of the plate shown in FIG. 3;

FIG. 10 is a cross-sectional view illustrating still another example of the plate shown in FIG. 3; and

FIG. 11 is a flowchart illustrating a method of processing a substrate according to still another example embodiment of the present invention.

### BEST MODE FOR CARRYING OUT THE INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “lon” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

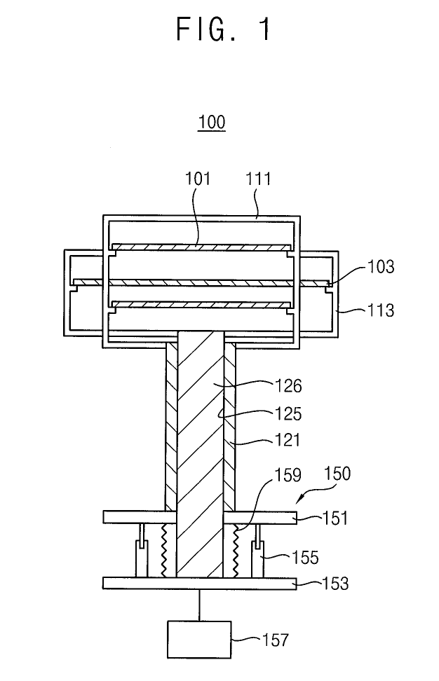

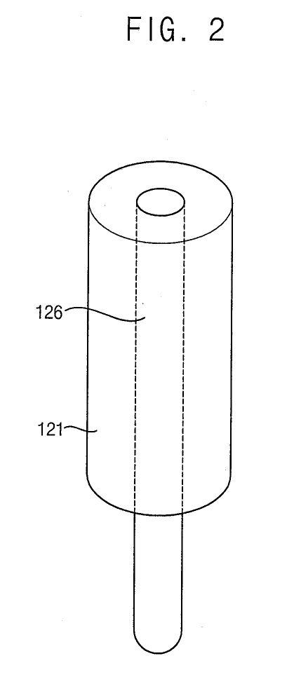

FIG. 1 is a cross-sectional view illustrating an elevator according to an example embodiment of the present invention, and FIG. 2 is a perspective view illustrating first and second driving shafts shown in FIG. 1.

Referring to FIGS. 1 and 2, an elevator 100, according to an example embodiment of the present invention, may include a first support unit 111, a second support unit 113, a first driving shaft 121, a second driving shaft 126 and a driving unit 150.

The first support unit 111 may support first plates 101. Here, the first plates 101 may be disposed parallel with each other in a horizontal direction. For example, the first plates 101 may be chucks for supporting each of substrates.

The first support unit 111 may include a plurality of first support columns (not shown), a first upper panel (not shown) connecting upper portions of the first support columns with one another, and a first lower panel (not shown) connecting lower portions of the first support columns with one another. Further, first protrusions (not shown) or first grooves (not shown) may be formed to partially support lower surfaces of the first plates 101 at inner surfaces of the first support columns.

The second support unit 113 may support a second plate 103. Here, the second plate 103 may be disposed parallel to the first plates 101 between the first plates 101. When the first plates 101 are used as the chucks to support the substrates, the second plate 103 may be used as a space-dividing member, which divides processing spaces to process the substrates supported by the chucks.

The second support unit 113 may include a plurality of second support columns (not shown), a second upper panel (not shown) connecting upper portions of the second support columns with one another, and a second lower panel (not shown) connecting lower portions of the second support columns with one another. Further, second protrusions (not shown) or second grooves (not shown) may be formed to partially support lower surfaces of the second plate 103 at inner surfaces of the second support columns.

The first driving shaft 121 may be connected with the first support unit 111 to elevate the first support unit 111. Thus, the first plates 101 supported by the first support unit 111 may move up and down by allowing the driving shaft 121 to elevate the first support unit 111. As a result, in a case where the first plates 101 support the substrates, the first plates 101 may be elevated to thereby move the substrates in a vertical direction.

A hollow 125 may be formed in the first driving shaft 121, and the second driving shaft 126 may be disposed through the hollow 125.

According to some example embodiments of the present invention, the first driving shaft 121 may have a cylindrical shape. In this case, the first driving shaft 121 may have a first diameter.

The second driving shaft 126 may be connected with the second support unit 113 to move the second support unit 113 up and down. Thus, the second plate 103 supported by the second support unit 113 may move up and down by allowing the second driving shaft 126 to move the second support unit 113 up and down.

The first driving shaft 121 may be mechanically connected with the second driving shaft 126. For example, the second driving shaft 126 may be inserted in the hollow 125 of the first driving shaft 121.

According to some example embodiments of the present invention, the second driving shaft 126 may have a cylindrical shape. In this case, the second driving shaft 126 may have a second diameter smaller than the first diameter of the first driving shaft 121. Further, the second driving shaft 126 may have a height greater that of the first driving shaft 121 so that the second driving shaft 126 passes through the hollow 125 of the first driving shaft 121.

The driving unit 150 may be mechanically connected with the first and second driving shafts 121 and 126. The driving unit 150 may provide a driving force to move the first and second driving shafts 121 and 126 in the vertical direction.

The driving unit 150 may include a first flange 151, a second flange 153, a distance-adjusting member 155 and a driving section 157.

The first flange 151 may be mechanically connected with a lower portion of the first driving shaft 121. Thus, when the first flange 151 moves up and down, the first support unit 111 mechanically connected with the first driving shaft 121 may move up and down. The first flange 151 may have a through-hole to allow the second driving shaft 126 to pass therethrough. Thus, the second driving shaft 126 may protrude downward through the first flange 151.

The second flange 153 may be disposed parallel to the first flange 151 thereunder. The second flange 153 may be mechanically connected with a lower portion of the second driving shaft 126. Thus, when the second flange 153 moves up and down, the second driving shaft 126 may move up and down.

The driving section 157 may be disposed under the second flange 153 and may be mechanically connected with the second flange 153.

The distance-adjusting member 155 may mechanically connect the first and second flanges 151 and 153 with each other. The distance-adjusting member 155 may maintain a constant distance between the first and second flanges 151 and 153 or may reduce the distance between the first and second flanges 151 and 153. Thus, when the distance between the first and second flanges 151 and 153 is maintained constant, and the second flange 153 is moved up and down by the driving section 157, the first flange 151 may move up and down as well. Further, when the distance between the first and second flanges 151 and 153 is varied by the distance-adjusting member 155, the first support unit 111 mechanically connected with the first flange 151 may move up and down. On the contrary, the second flange 153 may be moved relative to the first flange 151.

As a result, the first and second flanges may be individually moved up and down by the relative motion between the first and second flanges 151 and 153, i.e., by adjusting the distance between the first and second flanges 151 and 153, and both of the first and second flanges 151 and 153 may be simultaneously moved up and down by the driving section 157.

According to some example embodiments of the present invention, the distance-adjusting member may include a hydraulic or pneumatic cylinder. Meanwhile, the elevator 100 may further include a bellows surrounding the second driving shaft 126 between the first and second flanges 151 and 153.

According to some example embodiments of the present invention, the driving section 157 may include a hydraulic or pneumatic cylinder. Alternatively, the driving section 157 may include a motor and a linear motion guide.

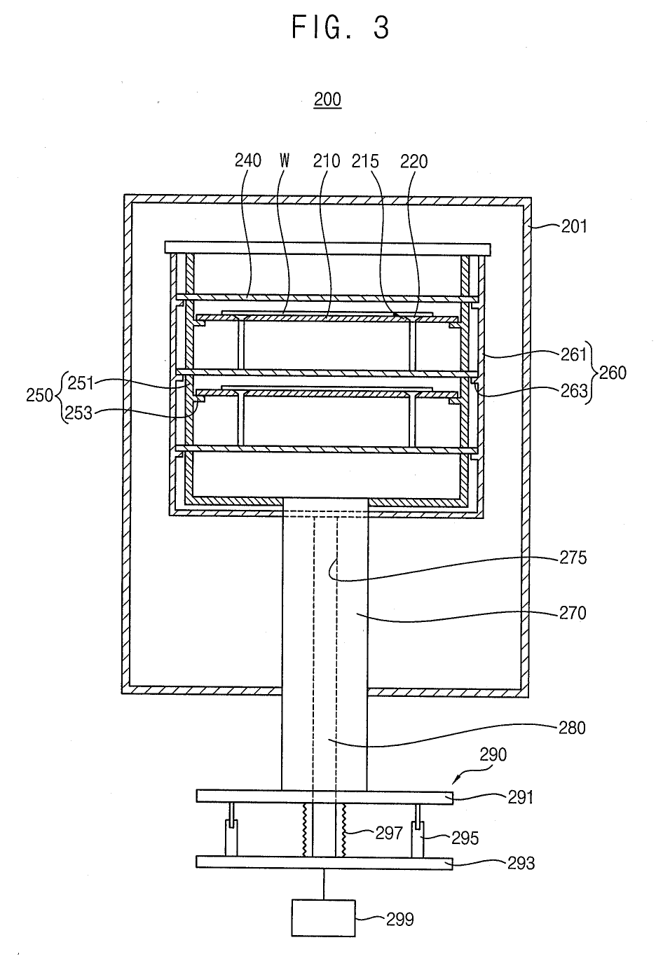

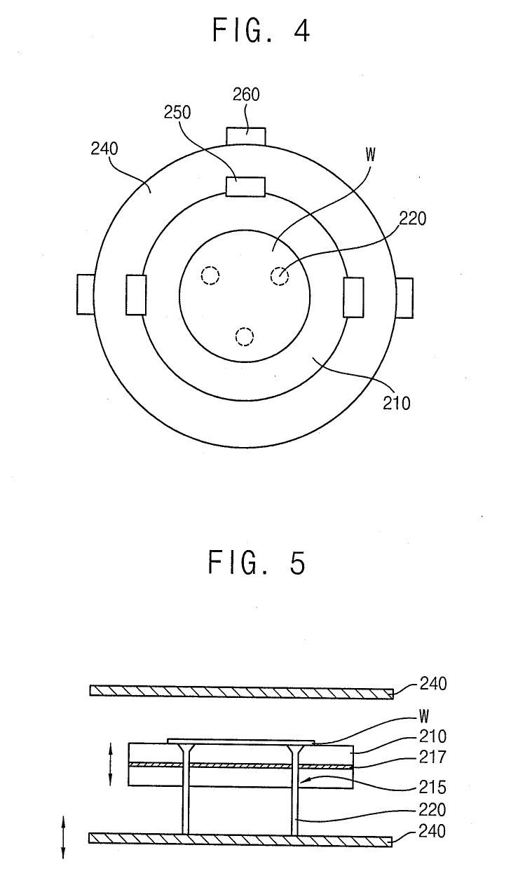

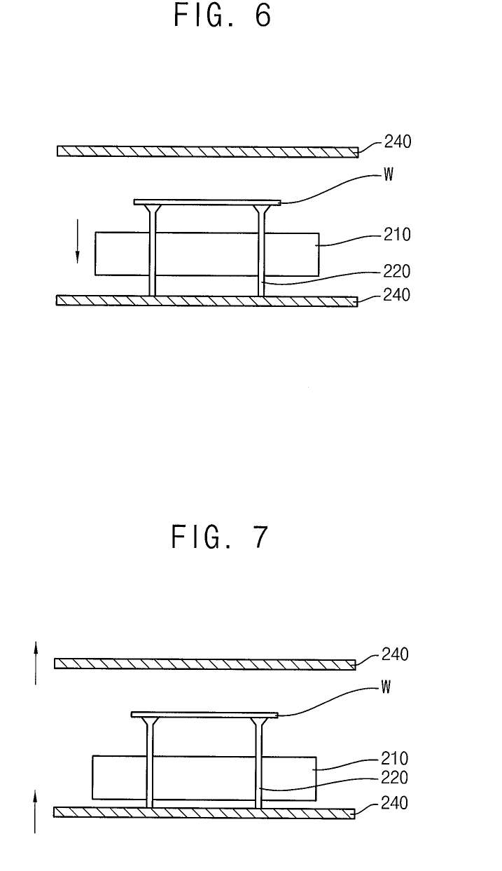

FIG. 3 is a cross-sectional view illustrating an apparatus for processing a substrate according to another example embodiment of the present invention; FIG. 4 is a plan view illustrating a state in which the substrate is supported in the substrate processing apparatus shown in FIG. 3; FIG. 5 is a cross-sectional view illustrating the substrate supported by first and second support units shown in FIG. 3; FIG. 6 is a cross-sectional view illustrating the substrate spaced apart from a chuck by the first support unit shown in FIG. 3; and FIG. 7 is a cross-sectional view illustrating the substrate spaced apart from the chuck by the second support unit shown in FIG. 3.

Referring to FIGS. 3 to 7, an apparatus 200 for processing a substrate, according to another example embodiment of the present invention, may include a process chamber 201, a plurality of chucks 210, a plurality of supports 220, a first support unit 250, a plate 240, a second support unit 260, a first driving shaft 270, a second driving shaft 280 and a driving unit 290.

The process chamber 201 may provide a process space for processing a plurality of substrates W. Though not shown in the figures, the substrate processing apparatus 200 may further include a heater to adjust a temperature in the process chamber 201.

The plurality of chucks 210 may be arranged parallel with one another and vertically in the process chamber 201. Each of the chucks 210 may have a disk shape. The chucks 210 may each be in contact with back surfaces of the substrates W and may support the substrates W while processing the substrates W. Because, the back surfaces of the substrates W are in full contact with the chucks 210 while processing the substrates W, an unwanted layer may be prevented from being formed on the back surfaces of the substrates W.

Each of the chucks 210 may have a plurality of through-holes 215. The plurality of supports 220 may be disposed through the through-holes 215 in a vertical direction. For example, each of the chucks 210 may have three through-holes 215, and three supports 220 may be disposed through the three through-holes 215.

According to some example embodiments of the present invention, heating members 217 may be disposed within the chucks 210. For example, each of the heating members 217 may include an electrical resistance hot wire extending in a zigzag pattern. The heating members 217 may be provided to heat the substrates W loaded on the chucks 210 to a process temperature.

Though not shown in the figures, thermocouples may each be disposed within the chucks 210 to measure the temperature of the chucks 210. Further, the chucks 210 may be electrically grounded.

According to some example embodiments of the present invention, each of the supports 220 may extend in the vertical direction and may have a head to support the back surfaces of the substrates W.

According to some example embodiments of the present invention, in a case where the plate 240 is elevated, the supports 220 may elevate the substrates W to thereby unload the substrates W from the chucks 210. A transfer unit (not shown) may move into spaces between the unloaded substrates W and the chucks, and the substrates W may be carried out from the process chamber 201 by the transfer unit. On the contrary, the transfer unit may load the substrates W on the elevated supports 220.

According to some example embodiments of the present invention, in a case where the chucks 210 move down, the substrates W may be supported by the supports 220 and thus may be unloaded from the chucks 210.

Meanwhile, the transfer unit may be disposed in a vacuum chamber (not shown) adjacent to the process chamber 201. Thus, a pressure in the process chamber 201 may be maintained constant while transferring the substrates W, thereby reducing the time required to transfer the substrates W.

The plate 240 may be disposed between the chucks 210. Particularly, the plate 240 may be disposed parallel to the chucks 210. For example, the plate 240 may have a disk shape. The plate 240 may divide process spaces to process the substrates W. For example, a process space in the process chamber 201 may be divided into a plurality of spaces to process the substrates W.

As shown in FIG. 3, the process space may be divided into a first space and a second space by a plurality of plates 240 to simultaneously process two substrates W. However, the process space may be divided into three or more spaces, and three or more substrates may be simultaneously processed.

Meanwhile, the plates 240 may support lower portions of the supports 220. Thus, in a case where the plates 240 move up and down, the supports 220 may move up and down together with the plates 240. In a case where the supports 220 move up and down, the substrates W may be spaced apart from the chucks 210 or may be supported by the chucks 210.

According to some example embodiments of the present invention, the substrate processing apparatus 200 may process the substrates W using a plasma. In this case, the plates 240 may include a conductive material so that a radio frequency power may be applied to the plates 240 to generate the plasma from a process gas.

According to some example embodiments of the present invention, the plates 240 may have a diameter greater than those of the chucks 210. In a case where the plates 240 have a diameter greater than those of the chucks 210, a substrate W in the second space may be prevented from being contaminated by impurities which are produced while processing a substrate W in the first space

The chucks 210 may be supported by the first support unit 250, and the plates 240 may be supported by the second support unit 260. According to some example embodiments of the present invention, a plurality of first support units 250 may extend parallel with one another in the vertical direction, and a plurality of second support units 260 may extend parallel with one another in the vertical direction. Particularly, the first support units 250 may be disposed inside the second support units 260.

Reference numerals 251, 253, 261, 263, 275, 291, 293, 295, 297 and 299 represent a first support column, a first protrusion, a second support column, a second protrusion, a hollow, a first flange, a second flange, a distance-adjusting member, a bellows and a driving section, respectively.

Meanwhile, further detailed descriptions for the first support unit 250, the second support unit 260, the first driving shaft 270, the second driving shaft 280 and the driving unit 290 will be omitted because these elements are similar to those already described with reference to FIGS. 1 and 2.

In the substrate processing apparatus according to the example embodiments of the present invention, processes of processing the substrates W may be individually performed in the spaces in which the substrates are disposed using the plasma. Further, the substrates W may be carried in and out by the transfer unit which is disposed in the vacuum chamber. Thus, the time required to perform the processes may be reduced.

Moreover, the substrate processing apparatus 200 may have improved throughput in comparison with a conventional single-type substrate processing apparatus because the substrates W are simultaneously processed by the substrate processing apparatus 200. Further, the back surfaces of the substrates W may be in full contact with upper surfaces of the chucks 210 to thereby prevent impurities from being formed on the back surfaces of the substrates W.

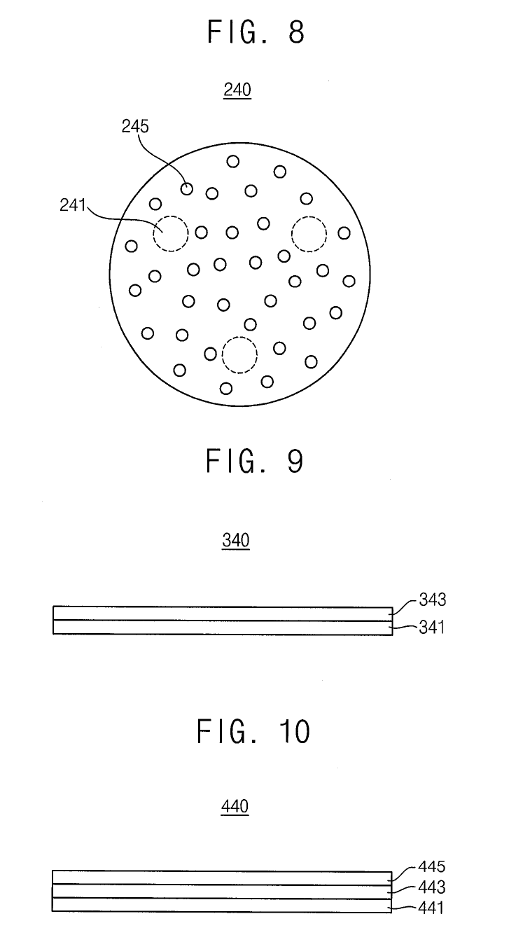

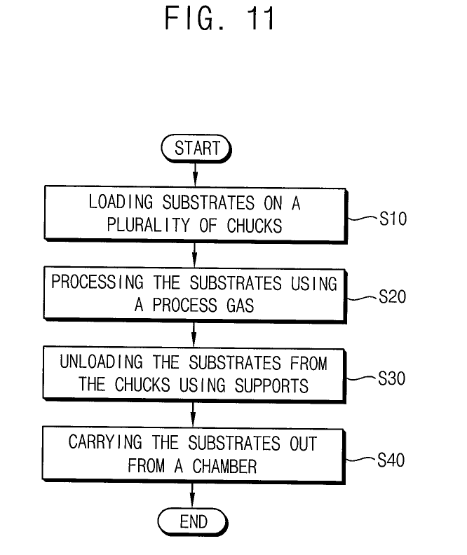

FIG. 8 is a plan view illustrating an example of the plate shown in FIG. 3; FIG. 9 is a cross-sectional view illustrating another example of the plate shown in FIG. 3; and FIG. 10 is a cross-sectional view illustrating still another example of the plate shown in FIG. 3.

Referring to FIG. 8, a plurality of holes 245 may be formed through the plate 240 to pass the process gas therethrough. In this case, the holes 245 may be uniformly formed in a remaining region except for a region 241 by which the supports 220 are supported. For example, the holes 245 may have a diameter of about 0.05 to about 5 mm. When the holes 245 have a diameter smaller than about 0.05 mm, it is difficult to pass the process gas through the holes 245. Further, when the holes 245 have a diameter greater than about 5 mm, impurities produced in the first space may be transferred into the second space through the holes 245.

According to some example embodiments of the present invention, high frequency energy may be applied to the plate 240 to generate the plasma from the process gas for processing the substrates W. In this case, the plate 240 may include a conductive material. Examples of the conductive material may include aluminum, tantalum, titanium, silver, and the like. These materials may be used alone, and an alloy thereof may be used as well.

According to some example embodiments of the present invention, when there is no need to generate the plasma from the process gas, the plate 240 may include an insulating material. For example, the plate 240 may include metal oxide, metal nitride, or the like. Particularly, the plate 240 may include aluminum oxide, aluminum nitride, or the like.

Meanwhile, a cooling line, through which a cooling agent, for example, deionized water, is circulated, may be disposed within the plate 240. The cooling line may be provided to adjust a temperature in the process chamber 201. For example, the cooling line may be used to lower the temperature of the substrates W.

Reference to FIG. 9, a plate 340 may have a dual-layer structure. For example, the plate 340 may include a conductive layer 341 and an insulating layer 343 on the conductive layer 341.

Reference to FIG. 10, a plate 440 may have a multilayer structure. For example, the plate 440 may include a conductive layer 441, an insulating layer 443 on the conductive layer 441 and an adiabatic layer 445 on the insulating layer 443.

FIG. 11 is a flowchart illustrating a method of processing a substrate according to still another example embodiment of the present invention.

Referring to FIGS. 3 and 11, each of a plurality of substrates W is loaded on the chucks 210 which are disposed parallel with each other and have the holes 215 (step S10). Here, back surfaces of the substrates W make contact with the upper surfaces of the chucks 210.

The substrates W are processed by using a process gas (step S20). Here, the process gas may be supplied into spaces between the substrates W and the plates 240 and may be excited into a plasma state by high frequency energy applied to the plates 240. Further, process conditions, for example, temperature, pressure, or the like, may be adjusted to process the substrates W.

The substrates W are unloaded from the chucks 210 by moving the supports 220 disposed through the holes 215 upward (step S30).

For example, the first flange 291 and the first driving shaft 270 may be moved downward by the distance-adjusting member 295 to thereby move the first support unit 250 and the chucks 210 connected with the first driving shaft 270 downward. As a result, the supports 220 move upward relative to the chucks 210, and thus the substrates W may be supported by the supports 220 and may be unloaded from the chucks 210.

Alternatively, the position of the first flange 291 is maintained constant, and the second flange 293 may be moved upward by the driving section 299 and the distance-adjusting member 295. That is, as the second flange 293 and the second driving shaft 280 move upward, the second support 260 and the plates 240 may move upward, and the supports 220 may move upward as well. As a result, the substrates W may be unloaded from the chucks 210 by the supports 220.

The substrates W unloaded from the chucks 210 are carried out from the process chamber 201 (step S40). Here, the transfer unit may move into the spaces between the unloaded substrates W and the chucks 210, and the substrates W may then be carried out from the process chamber 201.

### INDUSTRIAL APPLICABILITY

According to the example embodiments of the present invention as described above, a plurality of substrates may be processed in one chamber using a plasma. Particularly, chucks may be disposed to fully support back surfaces of the substrates in the chamber. Thus, an unwanted layer may be prevented from being formed on the back surfaces of the substrates.

Further, steps of loading and unloading the substrates may be performed by a transfer unit disposed in a vacuum chamber. Thus, the time required to process the substrates may be shortened and the throughput of the substrate processing apparatus may be improved.

Although the example embodiments of the present invention have been described, it is understood that the present invention should not be limited to these example embodiments but various changes and modifications can be made by those skilled in the art within the spirit and scope of the present invention as hereinafter claimed.

1. An elevator comprising:
first plates disposed in a horizontal direction with each other;
a first support unit supporting the first plates;
a second plate disposed parallel to the first plates between the first plates;
a second support unit supporting the second plate;
a first driving shaft connected with the first support unit, the first driving shaft having a hollow therein and extending in a vertical direction;
a second driving shaft connected with the second support unit, the second driving shaft extending through the hollow of the first driving shaft; and
a driving unit mechanically connected with the first and second driving shafts to move the first and second driving shafts in the vertical direction.

2. The elevator of claim 1, wherein the driving unit comprises:
a first flange connected with an end of the first driving shaft;
a second flange disposed parallel to the first flange under the first flange and connected with an end of the second driving shaft;
a driving section moving the second flange in the vertical direction; and
a distance-adjusting member connecting the first and second flanges with each other and adjusting a distance between the first and second flanges.

3. The elevator of claim 2, wherein the driving unit further comprises a bellows surrounding the second driving shaft between the first and second flanges.

4. An apparatus for processing a substrate comprising:
a process chamber;
a plurality of chucks disposed parallel with each other in the process chamber, the chucks supporting a plurality of substrates to make contact with back surfaces of the substrates and each having a plurality of through-holes; and
a plurality of supports disposed through the through-holes, the supports loading the substrates on the chucks and unloading the substrates from the chucks.

5. The apparatus of claim 4, wherein each of the chucks is in full contact with each of the back surfaces of the substrates.

6. The apparatus of claim 4, wherein the chucks are vertically movable to support the substrates and to unload the supported substrates.

7. The apparatus of claim 4, further comprising heaters disposed within the chucks to adjust a temperature of the substrates.

8. The apparatus of claim 4, further comprising a driving unit to simultaneously move the chucks in a vertical direction.

9. The apparatus of claim 8, further comprising a support unit supporting the chucks and extending in the vertical direction and a driving shaft connecting the support unit with the driving unit.

10. The apparatus of claim 4, further comprising a plurality of plates disposed parallel to the chucks under the chucks and dividing a space in the process chamber so that the substrates are processed in individual spaces.

11. The apparatus of claim 10, wherein the plates support ends of the supports and are vertically movable.

12. The apparatus of claim 10, wherein the plates include a conductive material.

13. The apparatus of claim 10, wherein the plates have a diameter greater than those of the chucks.

14. The apparatus of claim 10, further comprising a driving unit moving the plates in a vertical direction.

15. The apparatus of claim 14, further comprising a support unit supporting the plates and extending in the vertical direction and a driving shaft connecting the support unit with the driving unit.

16. The apparatus of claim 10, wherein each of the plates has a plurality of second through-holes to pass a gas for processing the substrates therethrough.

17. The apparatus of claim 16, wherein the second through-holes have a diameter of about 0.05 to about 5 mm.

18. The apparatus of claim 10, wherein the plates comprise at least one selected from the group consisting of aluminum, tantalum, titanium and silver.

19. The apparatus of claim 10, wherein the plates have a multilayer structure.

20. The apparatus of claim 19, wherein each of the plates comprises a conductive layer and an insulating layer on the conductive layer.

21. The apparatus of claim 19, wherein each of the plates comprises a conductive layer, an insulating layer on the conductive layer and an adiabatic layer on the insulating layer.

22. The apparatus of claim 10, wherein each of the plates has a cooling line configured to circulate a cooling agent.

23. The apparatus of claim 4, wherein the chucks comprise a conductive material.

24. The apparatus of claim 4, further comprising a heater adjusting a temperature in the process chamber.

25. An apparatus for processing a substrate comprising:
a process chamber;
a plurality of chucks disposed parallel with each other in the process chamber, the chucks each supporting a plurality of substrates to each make contact with back surfaces of the substrates and having a plurality of through-holes;
a plurality of supports disposed through the through-holes and movable in a vertical direction;
a first support unit supporting the chucks and extending in the vertical direction;
plates disposed parallel to the chucks under the chucks to support lower ends of the supports;
a second support unit supporting the plates and extending in the vertical direction;
a first driving shaft connected with the first support unit, the first driving shaft having a hollow therein and extending in the vertical direction;
a second driving shaft connected with the second support unit, the second driving shaft extending through the hollow of the first driving shaft; and
a driving unit mechanically connected with the first and second driving shafts to move the first and second driving shafts in the vertical direction.

26. A method of processing a substrate comprising:
loading a plurality of substrates on a plurality of chucks, respectively, the chucks being disposed parallel with each other in a process chamber and having a plurality of through-holes;
processing the substrates using a process gas;
unloading the substrates from the chucks by allowing supports to support the substrates, the supports being disposed through the through-holes and movable in a vertical direction; and
carrying the substrates spaced apart from the chucks out from the process chamber.

27. The method of claim 26, wherein the substrates are supported by the supports by moving the chucks downward.

28. The method of claim 26, wherein the substrates are supported by the supports by moving the supports upward.
